(19) United States
(12) Patent Application Publication
(10) Pub. No.: US 2023/0010682 A1
(43) Pub. Date: Jan. 12, 2023

(54) Touch Panel Device

(71) Applicant: Futaba Corporation, Mobara-shi (JP)

(72) Inventors: Koji TAJIMA, Mobara-shi (JP); Hiroaki EGUCHI, Mobara-shi (JP); Tomoya SATO, Mobara-shi (JP)

(21) Appl. No.: 17/858,874

(22) Filed: Jul. 6, 2022

(30) Foreign Application Priority Data
Jul. 7, 2021 (JP) 2021-112892

(51) Int. Cl. G06F 3/041; H01L 41/113

(52) U.S. Cl. CPC G06F 3/0414; H01L 41/1132

(57) ABSTRACT

An objective of the present invention is to provide a structure of a touch panel which may avoid degradation of visibility. A touch panel device includes a piezo film having a piezoelectric effect, a touch detecting section disposed at a first face of two faces of the piezo film, the two faces extending orthogonally to a thickness direction of the piezo film, wherein the touch detecting section has an electrode structure which is patterned for enabling detection of a touch position, a conductive layer formed at a second face of the two faces of the piezo film, the second face being opposite to the first face, and a coating layer disposed on the first face of the piezo film, wherein the first face is adhered to the touch detecting section via the coating layer by means of an adhesive.

### CROSS-REFERENCE TO RELATED APPLICATION

This application claims the priority benefit of Japanese Patent Application No. 2021-112892 filed Jul. 7, 2021, which is fully incorporated herein by reference.

### TECHNICAL FIELD

The present invention relates to a touch panel device which is configured to detect a touch position on an operating surface and to detect presses on the operating surface.

### BACKGROUND ART

Touch panel devices are known which have a position detecting function of detecting touch positions on an operating surface and a pressure detecting function of detecting a pressing force of the touch.

For example, Patent Document 1 discloses a touch panel device which combines an electrostatic capacitance detection system with a pressure detection system. This touch panel device is configured by stacking a touch detecting section, a piezo film and a conductive layer, the touch detecting section having an electrode structure which is patterned for enabling detection of a touch position, wherein the piezo film has a piezoelectric characteristic, and the conductive layer provides a reference potential. The piezo film generates a dielectric field upon pressure thereon in a thickness direction, which induces a potential difference between the touch detecting section and the conductive layer. Based on this potential difference, a pressing force on a touch panel is detected.

### CITATION LIST

### Patent Literature

Patent Document 1: JP 2018-504691 A

### SUMMARY OF THE INVENTION

In the touch panel device as disclosed in the Patent Document 1, the piezo film is adhered to the touch detecting section and conductive layer via an adhesive, such as an OCA (Optical Clear Adhesive).

A touch panel device having such a structure has the risk of degradation of a visibility of the touch panel, e.g., due to oxidative reaction (yellowing) of the piezo film caused by an additive in the adhesive in an environment with high temperature and high humidity and/or due to a scratch generated during forming the piezo film via a uniaxial drawing process.

Therefore, the present invention provides a structure of a touch panel which may avoid degradation of visibility.

In at least some embodiments, a touch panel device includes a piezo film having a piezoelectric effect, a touch detecting section disposed at a first face of two faces of the piezo film, the two faces extending orthogonally to a thickness direction of the piezo film, wherein the touch detecting section has an electrode structure which is patterned for enabling detection of a touch position, a conductive layer formed at a second face of the two faces of the piezo film, the second face being opposite to the first face, and a coating layer disposed on the first face of the piezo film, wherein the first face is adhered to the touch detecting section via the coating layer by means of an adhesive.

In this manner, an additive in the adhesive etc. is prevented from reaching the piezo film.

The present invention enables reduction of the visibility of the touch panel to be suppressed.

### BRIEF DESCRIPTION OF THE DRAWINGS

FIG. 1 shows an exemplary configuration of a touch panel device according to an embodiment of the present invention;

FIG. 2 schematically shows an overview of a stack structure of a touch panel according to the embodiment;

FIG. 3 schematically shows a stack structure of a touch panel according to a prior art example;

FIG. 4 schematically shows a stack structure of a touch panel according to a first embodiment;

FIG. 5 schematically shows the stack structure of the touch panel according to the first embodiment;

FIG. 6 schematically shows the stack structure of the touch panel according to the first embodiment;

FIG. 7 schematically shows a stack structure of a touch panel according to a second embodiment;

FIG. 8 schematically shows the stack structure of the touch panel according to the second embodiment;

FIG. 9 schematically shows the stack structure of the touch panel according to the second embodiment;

FIG. 10 schematically shows the stack structure of the touch panel according to the second embodiment; and

FIG. 11 shows a graph showing a change of a yellowing characteristic of a piezo film for the second embodiment.

### DETAILED DESCRIPTION OF THE PREFERRED EMBODIMENTS

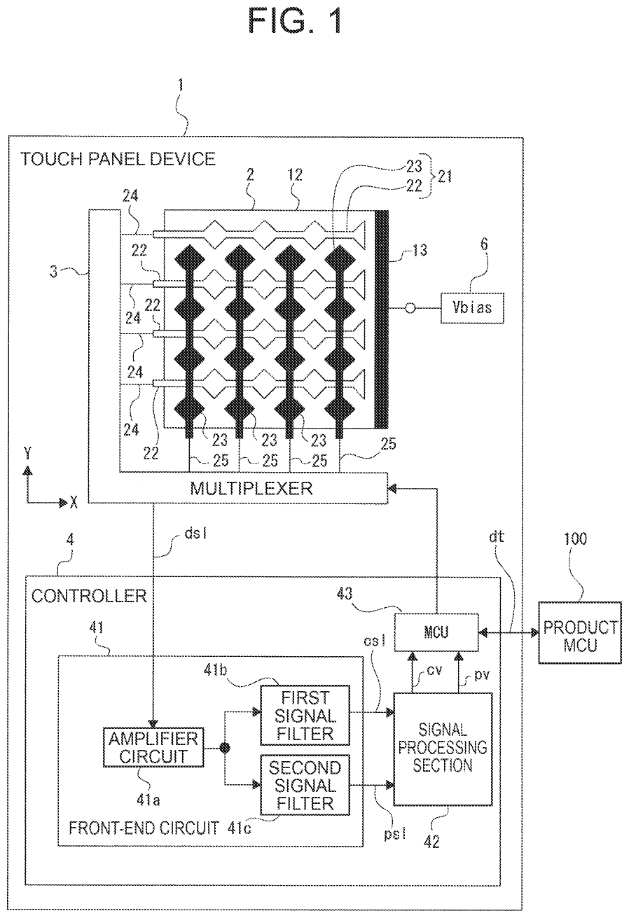

In the following description, embodiments will be described with reference to FIGS. 1 to 11. It is to be noted that features which are essential for implementing the embodiments, and peripheral features are extracted for showing in the Drawings and used for the description of the embodiments. Furthermore, it is to be noted that the Drawings are merely schematic, and that relations and ratios between thicknesses and plan view dimensions of structures depicted in the Drawings and the like are merely provided as examples. Therefore, various modifications are possible depending on designs and the like as far as such modifications do not depart from the technical idea of the present invention.

### <1. Exemplary Configurations of a Touch Panel Device>

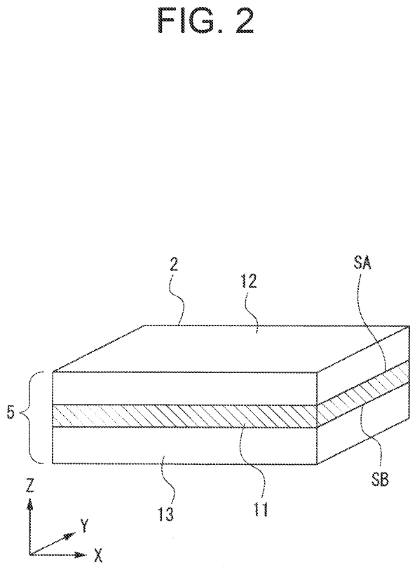

An exemplary configuration of a touch panel device 1 according to an embodiment will be described with reference to FIGS. 1 and 2.

The touch panel device 1 is intended to be mounted as a user interface device to various apparatuses. As such apparatuses, an electronic apparatus, a communication apparatus, an information processing device, a manufacture facility apparatus, a machining apparatus, a vehicle, an airplane, a building facility apparatus, and other apparatuses (display device) in a wide variety of fields may be conceivable, for example. The touch panel device 1 is employed as a device for inputting a user operation in such various apparatuses and products.

Here, user operation inputs shall include touching and/or pressing a touch panel or a layer of material covering it by a user. Furthermore, the user operation inputs shall include inputs by a finger of the user or a stylus.

FIG. 1 shows the touch panel device 1 and a product MCU (Micro Control Unit) 100, wherein the product MCU 100 represents a control device in a display device which the touch panel device 1 is mounted to. The touch panel device 1 will be operated to provide information about user operation inputs to the product MCU 100.

The touch panel device 1 includes a touch panel 2, a multiplexer 3 and a controller 4. The touch panel 2 is connected to the controller 4 via the multiplexer 3. Through this connection, the controller 4 (MCU 43 as described later) controls driving the multiplexer 3 (sensing).

When the touch panel device 1 is mounted as an operation input device to an apparatus, the controller 4 is connected to the product MCU 100. Through this connection, the controller 4 transmits operation information dt which has been sensed, to the product MCU 100.

The touch panel 2 is formed by a stack structure 5 which has a plurality of layers as shown in FIG. 2. In the stack structure 5 which will be described in detail later, each layer is generally planar and has at least a piezo film 11, a touch detecting section 12 and a conductive layer 13. In the following description, X-, Y- and Z-directions shall be defined as shown in FIG. 2. Specifically, the X-direction refers to a direction extending perpendicularly to a thickness direction of the touch panel 2. The Y-direction refers to a direction extending perpendicularly to the thickness direction of the touch panel 2 and orthogonally to the X-direction. The Z-direction refers to a direction extending perpendicularly to an XY-plane and parallel to the thickness direction of the touch panel 2. For these directions, the same applies to the following figures.

The piezo film 11 is a transparent, sheet-shaped, high molecular polymer having a piezoelectric characteristic, such as a polyvinylidene difluoride (PVDF) or a copolymer thereof, i.e., P(VDF-TrFE). The polyvinylidene difluoride is a highly conductive polymer which is excellent for high strength, chemical resistance and heat resistance, and has an excellent characteristic in processability and light transmittance. Furthermore, the piezo film 11 is not electrically connected to any element and is in a floating state.

The touch detecting section 12 is disposed at a first face SA of two faces of the piezo film 11, the two faces extending orthogonally to a thickness direction of the piezo film 11, wherein in a panel plane, the touch detecting section 12 has an electrode structure 21 which is patterned for enabling detection of a touch position (see FIG. 1).

Each of electrodes for the electrode structure 21 is formed e.g. from a metal which is suitable for deposition and patterning, such as an indium tin oxide (ITO), and/or from a conductive polymer having a light transmittance, such as PEDOT (Poly(3,4-EthyleneDiOxyThiophene)). This applies to the conductive layer 13 which will described below.

The conductive layer 13 is disposed at a second face SB of the piezo film 11 which is opposite to the first face SA. The conductive layer 13 is connected to a voltage bias source 6 which provides a constant potential. It is to be noted that the conductive layer 13 may be grounded.

The conductive layer 13 functions as a reference potential for the piezo film 11. A user operation input to the touch panel 2 applies a stress to the piezo film 11, which induces a voltage on the piezo film 11 due to the piezoelectric effect. The voltage change is detected through the electrode structure 21 of the touch detecting section 12. By detecting such a voltage change, it is possible to detect a degree of pressing by the user operation input.

Hereinafter, the electrode structure 21 of the touch detecting section 12 will be described. The electrode structure 21 includes a plurality of first electrodes 22 and a plurality of second electrodes 23 arranged therein.

Each of the first electrodes 22 extends along the X-direction and is arranged equidistantly in the Y-direction. Each of the first electrodes 22 is connected to the multiplexer 3 via a first conductive path 24.

Furthermore, each of the second electrodes 23 extends along the Y-direction and is arranged equidistantly in the X-direction. Each of the second electrodes 23 is connected to the multiplexer 3 via a second conductive path 25.

For example, the first electrodes 22 and second electrodes 23 are formed in the form of diamond shapes which are connected in a longitudinal direction of the electrodes, wherein the first and second electrodes 22 and 23 are arranged so as to intersect each other. In order to prevent conductive connection at intersection points between the first electrodes 22 and the second electrodes 23, e.g., an insulating layer (not shown) is formed at these intersection points. Electrostatic capacitances exist between the first electrodes 22 and the second electrodes 23 (e.g., capacitances at intersection points between the first and second electrodes 22, 23), wherein the electrostatic capacitances are changed due to the user operation input to the touch panel 2. Detecting such a change of the electrostatic capacitances allows a position of the user operation input to be detected.

It is to be noted that alternatively or in addition to arrangement with intersection as shown in FIG. 1, the first electrodes 22 and the second electrodes 23 may be arranged in a so-called single-layer electrode structure without intersection. In any case, a touch operating surface is formed in a region in which the first electrodes 22 and second electrodes 23 are arranged, wherein a structure is obtained which enables an operated position to be detected due to a capacitance change upon touch operation.

A transmission signal for sensing is successively outputted via a first conductive path 24 to a first electrode 22 which has been selected by the multiplexer 3, whereby a detection and scanning for the user operation input is achieved. Here, by performing the user operation input on the selected first electrode 22, a detection signal dsl is received through a second conductive path 25 from a second electrode 23 which is positioned around a position of the operation input. The position of the user operation input is determined based on the detection signal dsl.

The detection signal dsl includes a signal generated from the electrostatic capacitance change due to the user operation input, wherein a signal based on the voltage change due to the piezoelectric effect of the piezo film 11 is superposed to the signal generated from the electrostatic capacitance change. The detection signal dsl is provided to the controller 4 via the multiplexer 3.

The controller 4 includes a front-end circuit 41, a signal processing section 42 and an MCU 43. Furthermore, the front-end circuit 41 includes an amplifier circuit 41a, a first signal filter 41b and a second signal filter 41c.

As shown in the above-mentioned Patent Document JP 2018-504691 A, the detection signal dsl detected upon the detection and scanning at the touch panel 2 is successively provided to the front-end circuit 41, wherein the detection signal dsl is amplified by the amplifier circuit 41a.

The amplified detection signal dsl is provided to the first signal filter 41b and second signal filter 41c, wherein a piezoelectric signal psl and an electrostatic capacitance signal csl are separated and extracted from the detection signal dsl, the piezoelectric signal psl being based on the voltage change due to the piezoelectric effect of the piezo film 11 and the electrostatic capacitance signal csl being based on the electrostatic capacitance change at the electrode structure 21 due to the user operation input.

The first signal filter 41b is e.g., a low-pass filter having a cut-off frequency which is e.g., below a predetermined fundamental frequency, wherein the first signal filter 41b extracts the piezoelectric signal psl from the detection signal dsl. Further, the second signal filter 41c is e.g., a high-pass filter having a cut-off frequency is e.g., below the predetermined fundamental frequency and above the cut-off frequency of the first signal filter 41b, wherein the second signal filter 41c extracts the electrostatic capacitance signal csl from the detection signal dsl.

The extracted electrostatic capacitance signal csl and piezoelectric signal psl are provided to the signal processing section 42 from the first signal filter 41b and second signal filter 41c.

The signal processing section 42 provides an electrostatic capacitance value cv based on the received electrostatic capacitance signal csl and provides a piezoelectric value pv based on the piezoelectric signal psl.

The MCU 43 calculates position information, such as a coordinate value for the user operation input, e.g., from the received electrostatic capacitance value cv and control information for the multiplexer 3 and calculates pressure information from the piezoelectric value pv for the position, the pressure information being indicative of a degree of pressure of the operation input. The MCU 43 provides operation information dt including the calculated position information and pressure information to the product MCU 100. In this manner, a sensing result of the user operation input to the touch panel 2 is provided to the display device to which the touch panel device 1 is mounted to.

### <2. A Prior Art Example for a Stack Structure>

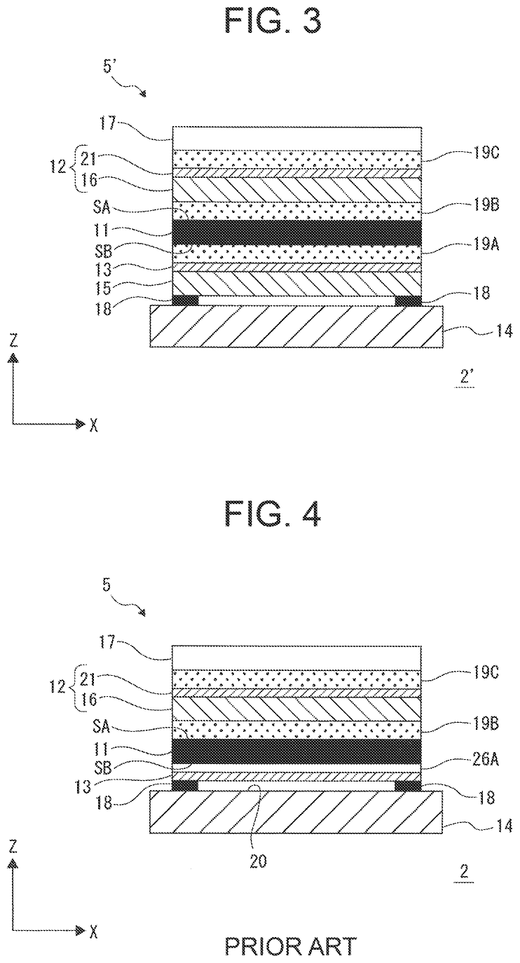

Now, a stack structure 5′ in a touch panel 2′ as a prior art example will be described with reference to FIG. 3.

Here, the stack structure 5′ includes, in a Z-direction starting from a region on a display panel 14, a dielectric element 15, a conductive layer 13, a piezo film 11, a transparent element 16, an electrode structure 21 and a cover element 17 in this order, as shown in FIG. 3.

The display panel 14 is configured as a thin display, such as a liquid crystalline panel or an organic EL (electro-luminescence) panel. The display panel 14 is controlled by the product MCU 100 so as to display an image.

The dielectric element 15 is formed from a polymer dielectric having a light transmittance, such as a polyethylene terephthalate (PET). The dielectric element 15 is adhered on one face to a surface of the display panel 14 via a double-sided adhesive tape 18, wherein the conductive layer 13 is formed on the other face of the dielectric element 15. A surface of the conductive layer 13 is adhered to a second face SB of the piezo film 11 via an adhesive 19A having a light transmittance. The adhesive 19A is e.g., an OCA. The same applies to adhesives 19B, 19C and 19D which will be described later.

The transparent element 16 is a glass pane, a resin film or the like which has a light transmittance and an insulating characteristic, wherein the transparent element 16 is adhered on one face to a first face SA of the piezo film 11 via the adhesive 19B. The electrode structure 21 is formed on the other face of the transparent element 16. Here, a touch detecting section 12 is formed from the transparent element 16 and the electrode structure 21. The piezo film 11 is insulated from the outside by the adhesives 19A and 19B, which prevents that electric charge generated on a surface of the piezo film 11 flows into the touch detecting section 12 and/or the conductive layer 13.

The cover element 17 is a glass pane, an acrylic plate or the like which has a light transmittance and an insulating characteristic, wherein the cover element 17 is adhered to the electrode structure 21 via the adhesive 19C. A surface of the cover element 17 forms an operating surface for performing operation inputs by a user and forms an image displaying surface for the display device which the touch panel device 1 is mounted to.

In the stack structure 5′ according to the above-described prior art example, the dielectric element 15 with the conductive layer 13 formed thereon is attached to the piezo film 11 via the adhesive 19A to form the stack structure 5′, which necessitates material costs and steps for the attachment related to the adhesive 19A. Further, for the attachment via the adhesive 19A and the like, there is the risk of gas inclusion and/or foreign substance introduction. Therefore, it is desirable to perform as few steps of the attachment as possible.

Furthermore, when the touch panel 2′ with such a stack structure 5′ is exposed to an environment with high temperature and high humidity, an additive in the adhesive 19A or the like may facilitate an oxidative reaction of the piezo film 11 and thus yellow the piezo film 11 so that the yellowing may be visible to human eyes, which may degrade optical characteristics of the touch panel 2′. Furthermore, the piezo film 11 is formed by means of a uniaxial drawing process, wherein a scratch formed during this process may impair the optical characteristics and/or a display quality of the touch panel 2′.

In the following description, embodiments of the present invention for solving the above-mentioned problems will be described.

### <3. First Embodiment of a Stack Structure>

A first embodiment of the stack structure 5 in the touch panel 2 will be described with reference to FIGS. 4 to 6. In the following description, the same reference signs will be used for the features which have been described once, and the corresponding description will be omitted.

In the stack structure 5 according to the present embodiment, an insulating layer 26A is formed on a second face SB of a piezo film 11, wherein a conductive layer 13 is formed on a surface of the insulating layer 26A, as shown in FIG. 4.

The insulating layer 26A is formed by using an organic resin material, such as an acryl-based, silicone-based, urethane-based material, and/or an inorganic material such as Si, wherein the insulating layer 26A is formed on the second face SB of the piezo film 11 by means of a predetermined layer application process. As used herein, the “layer application process” refers to layer application methods excluding layer application with an adhesive, such as a wet application with resin, a vapor deposition e.g. with Si, and a dry coating like sputtering.

On a surface of the insulating layer 26A which has been formed on the second face SB of the piezo film 11, the conductive layer 13 is formed by means of a predetermined layer application process. By forming the insulating layer 26A between the piezo film 11 and the conductive layer 13, electric charge generated on the surface of the piezo film 11 is prevented from flowing into the conductive layer 13.

A surface of the conductive layer 13 is adhered to the display panel 14 via a double-sided adhesive tape 18, wherein the double-sided adhesive tape 18 is formed in a frame shape. In this adhered state, a gap 20 which represents an air layer is formed between the conductive layer 13 and the display panel 14.

By forming the insulating layer 26A and the conductive layer 13 directly on the piezo film 11, it is unnecessary to adhere the piezo film 11 to the dielectric element 15 with the conductive layer 13 formed thereon by using the adhesive 19A as shown in FIG. 3. This enables material costs related to the adhesive 19A and dielectric element 15 to be reduced, wherein it is further possible to reduce steps of attachment by using the adhesive 19A.

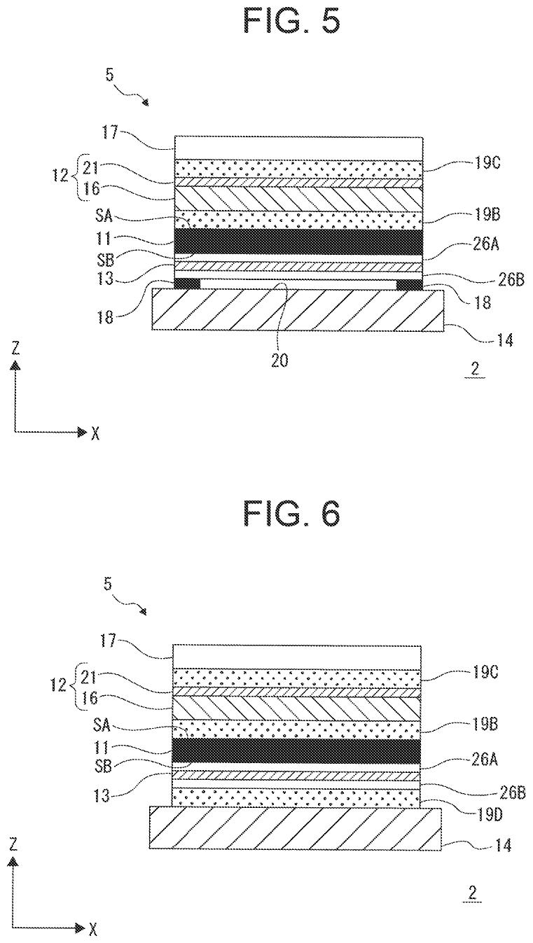

According to the present embodiment, a further insulating layer 26B may be formed on the conductive layer 13 applied on the insulating layer 26A, as shown in FIG. 5. The insulating layer 26B is formed by means of a similar layer application process as the above-described process. A surface of the insulating layer 26B is adhered to the display panel 14 via a double-sided adhesive tape 18.

In this case, the insulating layer 26B may be also adhered to the display panel 14 via the adhesive 19D, as shown in FIG. 6. In this manner, the adhesive 19D fills the air layer formed in the gap 20 between the insulating layer 26B and the display panel 14 as shown in FIG. 5 so that the reflectivity is suppressed, which may improve the visibility of the touch panel 2.

### <4. Second Embodiment of a Stack Structure>

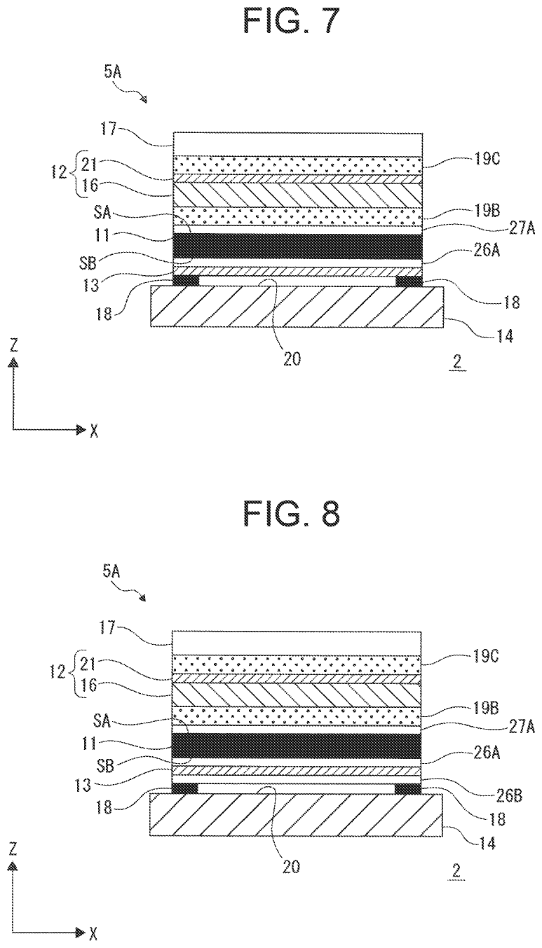

Next, a second embodiment of a stack structure 5A in the touch panel 2 will be described with reference to FIGS. 7 to 11.

As shown in FIG. 7, the stack structure 5A according to the present embodiment includes a coating layer 27A formed on a first face SA of the piezo film 11, wherein the piezo film 11 is adhered to the touch detecting section 12 via the coating layer 27A by using an adhesive 19B.

The coating layer 27A is formed by using an organic resin material, such as an acryl-based, silicone-based, urethane-based material, and/or an inorganic material such as Si, wherein the coating layer 27A is formed on the first face SA of the piezo film 11 by means of a similar layer application process as the above-described process. In this case, for the piezo film 11 having e.g., a thickness of 40 μm, the coating layer 27A has a thickness of 0.4 to 2.0 μm, for example.

By providing the coating layer 27A between the adhesive 19B and the piezo film 11 as described above, an additive in the adhesive 19B is prevented from reaching the piezo film 11 so that it is possible to prevent the piezo film 11 from being yellowed. Furthermore, by forming the coating layer 27A by means of the layer application process, it is possible to fill a scratch in the first face SA of the piezo film 11 so that the display quality of the touch panel 2 can be improved.

It is to be noted that the above-described configuration may be also applied to the stack structure 5A which includes a further insulating layer 26B formed on a surface of the conductive layer 13 as shown in FIG. 8.

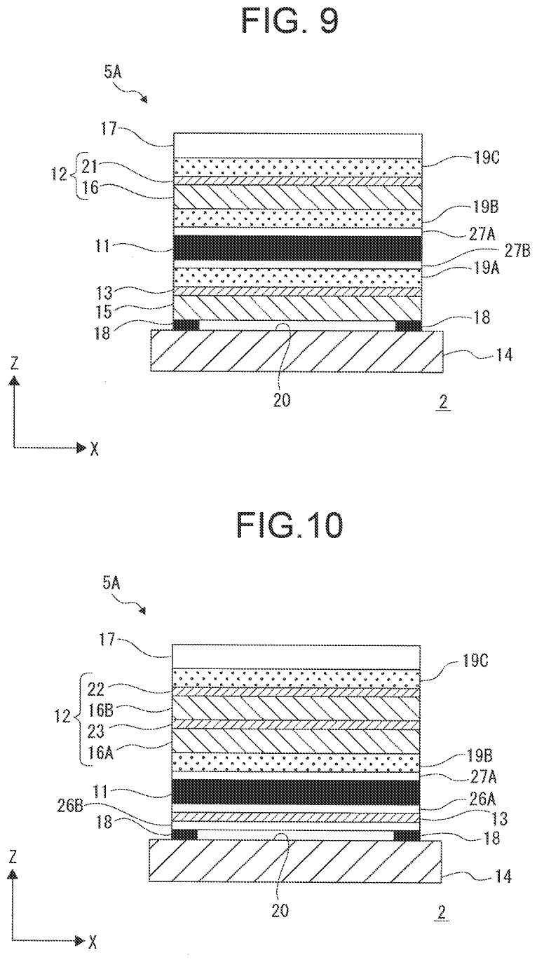

According to the present embodiment, in the case where the conductive layer 13 is formed on the dielectric element 15 and the dielectric element 15 is adhered to the piezo film 11 via an adhesive 19A, a coating layer 27B may be formed on a second face SB of the piezo film 11, as shown in FIG. 9.

The coating layer 27B is formed by means of a similar layer application process as the coating layer 27A. In this manner, the coating layer 27B is also provided between the adhesive 19A and the piezo film 11, which prevents the piezo film 11 from being yellowing due to an additive in the adhesive 19A and improves the display quality of the touch panel 2.

Although the above description has made reference to an application example to a glass touch sensor (GG (Glass/Glass) Structure) as an example of embodiment, it is to be noted that the above-described embodiment may be also applied to a film touch sensor (GFF (CoverGlass+Film/Film) Structure) having first and second electrodes 22 and 23 coated with films 16A and 16B, as shown in FIG. 10.

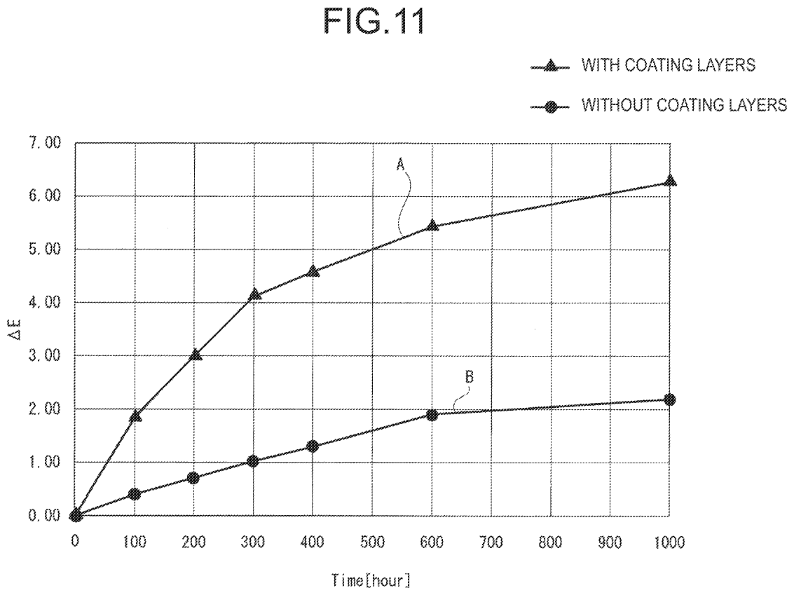

Hereinafter, the effect of yellowing prevention for the piezo film 11 will be described with reference to FIG. 11. FIG. 11 shows graphs of changes of evaluation values ΔE which indicate yellowing characteristics of the piezo film 11 over time in an environment with high temperature and high humidity (temperature: 85° C., humidity: 85%). A smaller evaluation value ΔE is considered as a higher yellowing resistance.

Graph A shows a change of the evaluation value ΔE of the piezo film 11 without coating layers 27A, 27B as shown in FIG. 3, while Graph B shows a change of the evaluation value ΔE of the piezo film 11 with the coating layers 27A and 27B with a thickness of 0.4 μm formed thereon as shown in FIG. 10.

After 1000 hours, the piezo film 11 without coating layers 27A, 27B has demonstrated the evaluation value ΔE of 6.3, while the piezo film 11 with the coating layers 27A and 27B has demonstrated the evaluation value ΔE of 2.2. Comparing these evaluation values ΔE shows that it is possible to remarkably suppress the yellowing of the piezo film 11 by providing the coating layers 27A and 27B.

### <5. Conclusion and Exemplary Variations>

The touch panel device 1 according to the first embodiment includes the piezo film 11 having a piezoelectric effect; the touch detecting section 12 disposed at the first face SA of two faces of the piezo film 11, the two faces extending orthogonally to the thickness direction (Z-direction) of the piezo film 11, wherein the touch detecting section 12 has the electrode structure 21 which is patterned for enabling detection of a touch position; the insulating layer 26A formed on the second face SB of the two faces of the piezo film 11 by means of a layer application process, the second face SB being opposite to the first face SA; and the conductive layer 13 formed on the insulating layer 26A (see FIG. 4).

In this manner, the piezo film 11 is formed integrally with the conductive layer 13 via the insulating layer 26A. Therefore, it is unnecessary to use the adhesive 19A as shown in FIG. 3 in order to adhere the piezo film 11 to the dielectric element 15 with the conductive layer 13 formed thereon. This enables material costs related to the adhesive 19A and dielectric element 15 to reduced, wherein it is further possible to reduce steps of attachment by using the adhesive 19A. Furthermore, reduction of steps for adhering results in reduction of the risk of quality failure which may occur during the attachment, such as gas inclusion and/or foreign substance introduction, which facilitates maintenance of the quality of the touch panel 2.

Moreover, it is possible to reduce the thickness and/or weight related to the adhesive 19A and dielectric element 15, which enables a more light-weight and thinner touch panel to be produced.

Further, the touch panel device 1 according to the first embodiment includes the further insulating layer 26B formed on the surface of the conductive layer 13 by means of a layer application process (see FIG. 5).

In this manner, the conductive layer 13 is insulated by the insulating layers 26A and 26B. Accordingly, it is prevented that electric charge flows out of the conductive layer 13 and/or into the conductive layer 13 from the outside, which enables a reference potential for the conductive layer 13 to be stabilized.

Furthermore, the display device with the touch panel device 1 mounted thereto according to the first embodiment includes the display panel 14 adhered to the insulating layer 26B by means of the adhesive 19D (see FIG. 6).

In this manner, the adhesive 19D fills the air layer formed in the gap 20 between the insulating layer 26B and the display panel 14 as shown in FIG. 5 so that the reflectivity is suppressed, which may improve the visibility of the touch panel 2.

The touch panel device 1 according to the second embodiment includes the piezo film 11 having a piezoelectric effect; the touch detecting section 12 disposed at the first face SA of two faces of the piezo film 11, the two faces extending orthogonally to the thickness direction (Z-direction) of the piezo film 11, wherein the touch detecting section 12 has the electrode structure 21 which is patterned for enabling detection of a touch position; and the conductive layer 13 disposed at the second face SB of the two faces of the piezo film 11, the second face SB being opposite to the first face SA, wherein the coating layer 27A is disposed on the first face SA of the piezo film 11, and the first face SA is adhered to the touch detecting section 12 via the coating layer 27A by means of the adhesive 19B (see FIG. 7).

By providing the coating layer 27A between the adhesive 19B and the piezo film 11 as described above, a substance forming part of the adhesive 19B is prevented from reaching the piezo film 11 so that it is possible to prevent the piezo film 11 from being yellowed.

Furthermore, the touch panel device 1 according to the second embodiment includes the coating layer 27B on the second face SB of the piezo film 11, wherein the second face SB is adhered to the conductive layer 13 via the coating layer 27B by means of the adhesive 19A (see FIG. 9).

By providing the coating layer 27B between the adhesive 19A and the piezo film 11, it is possible to prevent contact of the second surface SB of the piezo film 11 with the adhesive 19A. This may enable the piezo film 11 to be prevented from being yellowed, as described above.

Moreover, in the touch panel device 1 according to the second embodiment, the coating layers 27A and 27B may be formed by means of a layer application process, such as wet application of a resin-based material and/or dry application of an inorganic material.

With such a layer application process, scratches in the first face SA and second face SB of the piezo film 11 are filled to be less remarkable so that the display quality of the touch panel 2 can be improved. In addition, it is more difficult to cause wrinkles in a stack of the piezo film 11 and the coating layer 27A so that an improved operability for the attachment may be achieved and the display quality may be prevented from being reduced due to wrinkles.

Finally, the effect(s) described in the present disclosure is not limiting, but shown by way of example, wherein an embodiment is also possible which provides another effect, or partially provides the effect(s) described in the present disclosure. Furthermore, the embodiment(s) described in the present disclosure is merely an example, and the present invention is not limited to the above-described embodiment(s). Therefore, it is to be understood that various modifications other than the above-described embodiment(s) are also possible depending on the design etc. within a scope which does not depart from the technical idea of the present invention. It is to be noted that not all of combinations of features described in the embodiment(s) may not be necessarily essential to achieve the objective.

### REFERENCE SIGNS LIST

1 Touch panel device
2 Touch panel
5 Stack structure
11 Piezo film
12 Touch detecting section
13 Conductive layer
14 Display panel
15 Dielectric element
16 Transparent element
19A, 19B, 19C, 19D Adhesives
21 Electrode structure
26A, 26B Insulating layers
27A, 27B Coating layers

What is claimed is:

1. A touch panel device comprising:
a piezo film having a piezoelectric effect;
a touch detecting section disposed at a first face of two faces of the piezo film, the two faces extending orthogonally to a thickness direction of the piezo film, wherein the touch detecting section has an electrode structure which is patterned for enabling detection of a touch position;
a conductive layer disposed at a second face of the two faces of the piezo film, the second face being opposite to the first face; and
a first coating layer disposed on the first face of the piezo film,
wherein the first face is adhered to the touch detecting section via the first coating layer by means of an adhesive.

2. The touch panel device according to claim 1, further comprising:
a second coating layer disposed on the second face of the piezo film,
wherein the second face is adhered to the conductive layer via the second coating layer by means of an adhesive.

3. The touch panel device according to claim 2,
wherein the first coating layer and second coating layer are formed by wet application of a resin-based material.

4. The touch panel device according to claim 2,
wherein the first coating layer and second coating layer are formed by dry application of an inorganic material.
